(19) United States
(12) Patent Application Publication
(10) Pub. No.: US 2004/0089905 A1
(43) Pub. Date: May 13, 2004

(54) Magnetic sensor using spin injection through a semiconductor with a graded doping profile

(76) Inventors: Viatcheslav V. Ossipov, Mountain View, CA (US); Alexandre M. Bratkovski, Mountain View, CA (US)

Correspondence Address: HEWLETT-PACKARD COMPANY, Intellectual Property Administration, P.O. Box 272400, Fort Collins, CO, 80527-2400, US

(21) Appl. No.: 10/702,526

(22) Filed: Nov. 5, 2003

Related U.S. Application Data
(63) Continuation-in-part of application No. 10/284,360, filed on Oct. 31, 2002.

(51) Int. Cl. H01L 21/00; H01L 29/82

(52) U.S. Cl. 257/424; 438/48; 257/427; 257/422

(57) ABSTRACT

A magnetic sensor uses injection of spin-polarized electrons between magnetized regions via a semiconductor and spin precession of electrons that a magnetic field being measured causes in the semiconductor. The sensor can include donor n⁺-doped δ-layers and acceptor doped transition layers at one or both interfaces between magnetized regions and the semiconductor region. The properties of the δ-doped layers and the transition layers can be adjusted to improve efficiency of injection of spin-polarized electrons into the semiconductor at small voltage between about 25 and 50 mV. One geometry for the sensor has the magnetized regions that are laterally spaced apart on a major surface of a substrate with the semiconductor being either between or adjacent to the magnetic regions to form a current path for spin-polarized electrons.

### CROSS-REFERENCE TO RELATED APPLICATIONS

This patent document is a continuation-in-part and claims the benefit of the earlier filing date of U.S. patent application Ser. No. 10/284,360, filed Oct. 31, 2002, entitled: “Magnetic Sensor Based on Efficient Spin Injection into Semiconductor”, which is hereby incorporated by reference in its entirety. This patent document is also related to and hereby incorporates by reference in its entirety co-owned U.S. patent application Ser. No. 10/284,183, filed Oct. 31, 2002, entitled: “Efficient Spin-Injection Into Semiconductors”.

### BACKGROUND

Traditional magnetic sensors often employ coils for detection or measurement of changing magnetic fields. These traditional sensors are generally difficult to fabricate in integrated circuits. Magnetic sensors based on the Hall effect can be fabricated using integrated circuit process techniques and can measure a magnetic field, but the measurement signal strength resulting from measurement of the Hall effect generally decreases with the size of the magnetic sensor. Some other magnetic sensors, which have been proposed and developed, include magnetic read heads that use variations of magnetic configurations, i.e., the reconstruction of domain structures in ferromagnets under externally applied magnetic fields. This mechanism does not ensure the operating speed and the sensitivity required for ultrafast sensors of nanometer proportions.

More generally, pursuit of ultrafast solid-state devices of nanometer proportions has led to the development of magnetoelectronics and spintronics, which exploit the properties of ferromagnetic materials. Tunnel magnetoresistance (TMR), for example, is one focus for development of devices containing ferromagnetic materials. TMR is typically observed in structures made of two ferromagnetic layers separated by a thin insulating tunnel barrier. A tunnel current through the tunnel barrier may differ significantly depending on whether the magnetizations of the ferromagnetic layers are parallel (low resistance) or anti-parallel (high resistance).

Giant magnetoresistance (GMR), which is a phenomenon where a relatively small change in the magnetization of a magnetic layer results in a large change in device resistance, has found applications in storage technology.

Recent studies of giant ballistic magnetoresistance have observed that the transport of current through the very short constriction of a nanocontact for nickel (Ni) and some other nanowires appears to conserve electron momentum, so that electrons crossing a nanocontact having an area of a few square nanometers experience ballistic transport. The contact resistance for these structures can change by close to ten-fold (or about 1,000%) depending on magnetizations of the nanowire and the contact.

Another area of interest is the injection of spin-polarized carriers, mainly spin-polarized electrons, into semiconductors. One reason this phenomenon is attractive for device development is the relatively large spin-coherence lifetime of electrons in semiconductors, and the possibilities for use in ultrafast devices. The possibility of spin injection from magnetic semiconductors and half-metallic magnets into nonmagnetic semiconductors has been demonstrated in a number of recent publications. Room-temperature spin injection from ferromagnets into semiconductors has also been demonstrated albeit with small efficiency.

A magnetic sensor that is ultrafast and scalable down to nanometer dimensions is sought.

### SUMMARY

In accordance with an exemplary embodiment of the invention, a magnetic sensor includes: a first magnetized region; a second magnetized region; a semiconductor region; a first δ-doped layer between the first magnetized region and the semiconductor region; and a second δ-doped layer between the second magnetized region and the semiconductor region. The semiconductor region, which is in a path of a current between the first magnetized region and the second magnetized region, has a graded doping profile, for example, including an p-type transition layer between the n-type semiconductor region and one of the n-type δ-doped layers.

Another embodiment of the invention is a method for forming a magnetic sensor. The method includes forming a first magnetized region, a second magnetized region, and a semiconductor region having a first interface with the first magnetized region and a second interface with the second magnetized region. A first δ-doped layer can be formed at the first interface, between the first magnetized region and the semiconductor region. The method can further include doping a first portion of the semiconductor region at the first interface so that the first portion of the semiconductor region has a band gap energy that is less than a band gap energy elsewhere in the semiconductor region.

In accordance with another embodiment of the invention, a magnetic sensor includes: a substrate containing a semiconductor material; a first magnetized region overlying a first area of a surface of the substrate; and a second magnetized region overlying a second area of the surface of the substrate. The first area and the second area are spaced laterally apart, and the first and second magnetized regions respectively form first and second interfaces with the semiconductor material.

A method for forming a magnetic sensor in accordance with this embodiment of the invention includes forming a first magnetized region overlying a first area of a substrate, and forming a second magnetized region overlying a second area of the substrate. The first and second areas are laterally spaced apart, and the first and second magnetized regions respectively form first and second interfaces with a semiconductor material in the substrate.

### BRIEF DESCRIPTION OF THE DRAWINGS

FIG. 1 illustrates an exemplary magnetic sensor according to an embodiment of the invention using magnetic-semiconductor-magnetic heterostructures with δ-doped layers and a graded semiconductor layer to improve efficiency of injection of spin-polarized electrons.

FIG. 2 illustrates an exemplary magnetic sensor according to an embodiment of the invention sensitive to a magnetic field component parallel to the surface of the magnetic sensor and using magnetized layers of different thickness on the surface of a semiconductor layer.

FIG. 3 illustrates an exemplary magnetic sensor according to an embodiment of the invention sensitive to a magnetic field component perpendicular to the surface of the magnetic sensor and using magnetized regions on opposite sides of a raised a semiconductor region.

FIGS. 4A and 4B illustrate exemplary energy band diagrams respectively at equilibrium and under bias for the magnetic sensor when the magnetic sensor lacks δ-doped or graded semiconductor layers.

FIGS. 5A and 5B illustrate exemplary energy band diagrams respectively at equilibrium and under bias for a magnetic sensor in accordance with an embodiment of the invention including δ-doped and graded semiconductor layers.

FIG. 6 illustrates the density of electronic states of ferromagnetic nickel.

FIGS. 7A, 7B, and 7C illustrate a process for fabricating the magnetic sensor of FIG. 1.

FIGS. 8A, 8B, 8C, and 8D illustrate an exemplary manufacturing process for the sensor of FIG. 2.

FIGS. 9A, 9B, and 9C illustrate an exemplary manufacturing process for the sensor shown in FIG. 3.

Use of the same reference symbols in different figures indicates similar or identical items.

### DETAILED DESCRIPTION

For simplicity and illustrative purposes, the principles of the present invention are described by referring mainly to exemplary embodiments thereof. In the following description, numerous specific details are set forth in order to provide a thorough understanding of the present invention. However, the present invention may be practiced without limitation to these specific details. In other instances, well known methods and structure have not been described in detail so as not to unnecessarily obscure the present invention.

In accordance with an aspect of the invention, an ultrafast nanosize magnetic sensor senses a magnetic field varying at frequencies up to 100 GHz or more. The magnetic sensor can be formed as a heterostructure that includes a semiconductor between magnetized layers or regions. The magnetization of one magnetized region is approximately perpendicular to the magnetization of the other magnetized region. The heterostructure optionally includes thin, heavily-doped semiconductor layers (δ-doped layers) and doped transition layers at one or both of the interfaces of the semiconductor with the magnetized layers.

Operation of the heterostructure as a magnetic sensor relies on: (i) injection of spin polarized electrons from the first magnetized region into the semiconductor so that the interface of the first magnetized region with the semiconductor acts as a spin polarizer; (ii) spin ballistic transport of spin polarized electrons through the semiconductor; (iii) the measured magnetic field causing precession of electron spin during the transport of injected electrons through the semiconductor; and (iv) operation of the interface between the semiconductor and the second magnetized region as a spin filter so that the spin precession causes a variation in the conductivity of the magnetic sensor.

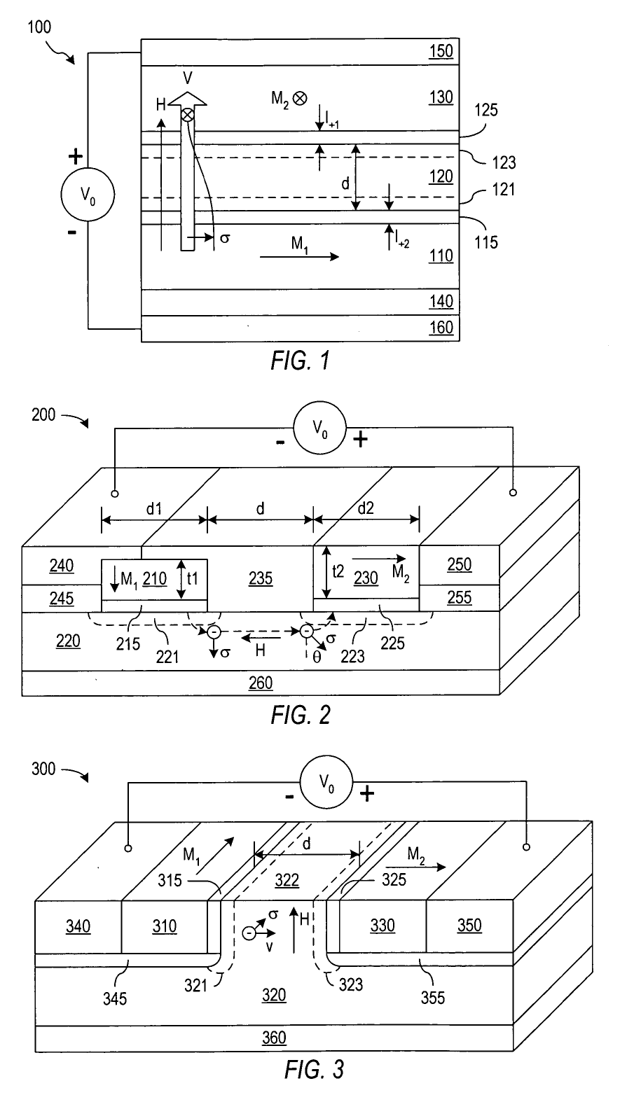

FIG. 1 illustrates a magnetic sensor 100 according to an exemplary embodiment of the present invention. As shown, magnetic sensor 100 includes a semiconductor layer 120 between magnetized layers 110 and 130. When a bias voltage V₀ having the polarity illustrated in FIG. 1 is applied to sensor 100, electrons flow from magnetized layer 110, through semiconductor layer 120, into magnetized layer 130. A portion of the current is made of spin-polarized electrons that initially have a spin a in a direction that depends on the magnetization M₁ of layer 110. The magnetic field H being measured causes the spin of the electrons in semiconductor layer 120 to precess about the direction of magnetic field H, which changes the conductivity of sensor 100 as described further below.

Efficient operation of sensor 100 requires that a high percentage of the electrons remain spin-polarized when crossing through the interface between magnetized layer 110 and semiconductor layer 120 and the interface between semiconductor layer 120 and magnetized layer 130. Thin heavily n⁺-doped semiconductor layers (also referred to as δ-doped layers) 115 and 125 are at the respective interfaces of semiconductor layer 120 with magnetized layers 110 and 130 to improve the efficiency of injection of spin polarized electrons across the interfaces. The δ-doped layers 115 and 125 can significantly increase the efficiency of injection of spin-polarized electrons across interfaces between semiconductor and the magnetized material. The δ-doped layers 115 and 125 are preferably thin (e.g., about 2 nm thick) layers of a semiconductor that is heavily doped, e.g., having a donor concentration greater than or equal to about 10²⁰ cm⁻³. Some conditions for the parameters of an exemplary embodiment of δ-doped layers 115 and 125 are presented below.

Magnetized layers 110 and 130 can be made of the same material or different materials and have respective net magnetizations M₁ and M₂. For reasons described further below, the magnetization M₁ of magnetized layer 110 is substantially perpendicular to the magnetization M₂ of magnetized layer 130. The deviation magnetizations M₁ and M₂ from being perpendicular to each other should generally be less than about 30° and preferably less than about 100. Magnetizations M₁ and M₂ in FIG. 1 are directed along the major surfaces of magnetized layers 110 and 130 for measurement of a magnetic field component perpendicular to magnetized layers 110 and 130. Alternatively, other configurations of magnetizations M₁ and M₂ relative to the major surfaces of magnetized layers 110 and 130 could also provide a suitably perpendicular arrangement. As described further below, the directions of magnetizations M₁ and M₂ control which component of a magnetic field H the magnetic sensor 100 measures.

Any material capable of having a net magnetization may be suitable for magnetized layers 110 and 130. Ferromagnetic materials such as iron (Fe), nickel (Ni), cobalt (Co), NiMnSb, CrO₂, Fe₂O₃, LaSrMnO₃, GaAs:Mn, ZnO:Mn, and alloys or combinations of these materials are some of the most common examples of materials that can provide a net magnetization. However, ferrimagnetic material such as FeO₄, amorphous magnetic materials such as Fe₈₀B₂₀, or other materials (e.g., with helically arranged local magnetizations) having net non-zero magnetization can also provide spin-polarized electrons for operation of magnetic sensor 100 as described further below.

The thicknesses of magnetized layers 110 and 130 are generally not critical to operation of sensor 100. However, as described further below, forming magnetized layer 110 or 130 of a ferromagnetic material that is thinner than the average magnetic domain wall width of the ferromagnetic material can simplify formation of magnetized layers 110 and 130 that have magnetizations M₁ and M₂ directed along the major surfaces of magnetized layers 110 and 130.

Semiconductor layer 120 may be formed from various semiconductor materials including but not limited to Si, GaAs, ZnTe, GaSb, GaP, Ge, InAs, CdSe, InP, InSb, CdTe, CdS, ZnS, ZnSe, AlP, AlAs, AlSb, and also alloys and combinations of these materials, including Ga₁₋ₓAlₓAs, Ga₁₋ₓInₓAs, Ga₁₋ₓInₓAs_{1-y}P_{y}, Zn₁₋ₓCd, and GeₓSi₁₋ₓ. In general, semiconductor layer 120 is preferably formed from materials with relatively long time τ_{S} of electron spin relaxation. Materials such as GaAs, GaInAs, Ge, ZnSe, and ZnCdSe when negatively doped are known to have relatively large spin relaxation time τ_{S} (e.g., greater than about 1 ns) at room temperature.

Optionally, semiconductor region 120 includes one or two transition layers 121 and 123 near the interfaces with one or both of magnetized layers 110 and 130. In one embodiment, transition layers 121 and 123, formed between n+ δ-doped layers 115 and 125 and n-doped neutral semiconductor region 120, are p-doped, causing semiconductor layer 120 to have a graded doping profile. The condition of an exemplary acceptor concentration (of p-dopant) in transition layers 121 and 123 is given below. Because of the particular doping profile, where an n+ δ-doped layer 115 or 125 with positive space charge is adjacent to a p-doped transition layer 121 or 123 with negative space charge, shallow potential wells form near δ-doped layers 115 and 125 in equilibrium where no bias voltage is applied. These shallow potential wells change the conduction band bottom when the bias voltage V₀ is applied to the device. This can enable more precise control of the energy cutoff for electrons injected into the conduction band of the semiconductor layer and, therefore, allow an efficient injection of electrons with highest spin polarization at small bias voltages, e.g., between 24 and 50 mV.

The thickness d of semiconductor layer 120 is preferably selected so that electrons conserve their spin orientation during transit through semiconductor layer 120, i.e., spin ballistic transport is desired. For spin ballistic transport, a transit time τ_{d} of the electrons through semiconductor layer 120 should be substantially equal to or less than the spin-relaxation coherence time τ_{S} of the electrons in semiconductor layer 120.

Transit time τ_{d} for electrons crossing semiconductor layer 120 is equal to the ratio of the thickness d of semiconductor layer 120 and the drift velocity v of the electrons traversing semiconductor layer 120. The drift velocity v in turn depends on the electron mobility μₙ, the diffusion constant Dₙ in semiconductor layer 120, and the electric field E resulting from an applied voltage V₀. The condition that transit time τ_{d} be less than spin-relaxation time τ_{S} limits the thickness d to being less than a maximum thickness dₘₐₓ of semiconductor layer 120 as indicated in Equation (1). The maximum thickness dₘₐₓ is typically less than about 1 μm for a suitable semiconductor material such as n-type ZnSe or GaAs.

d<dₘₐₓ=\sqrt{Dₙτₛ}+μEτₛ (1)

In sensor 100, the distance d between magnetized layers 110 and 130 (i.e., the thickness of semiconductor layer 120) should satisfy Equation (1) to provide ballistic transport of spin polarized electrons in semiconductor layer 120. The δ-doped layers 115 and 125 and transition layers 121 and 125 are preferably much thinner than d.

Sensor 100 further includes an electrode 140 and a substrate 160 below magnetized layer 110. Electrode 140 is preferably made of a metal or other conductive material that is electrically connected to magnetized layer 110. An electrode 150 electrically connects to magnetized layer 130. Use of electrodes 140 and 150 and substrate 160 in sensor 100 are optional because magnetized layers 110 and 130 may directly act as electrodes.

In an exemplary embodiment of the invention, electrodes 140 and 150 contain antiferromagnetic materials such as FeMn, IrMn, NiO, MnPt (L₁₀), α-Fe₂O₃, or a combination thereof. The antiferromagnetic layers in electrodes 140 and 150 are adjacent to respective magnetized layers 110 and 130 and may be used to help pin the mutually perpendicular magnetizations M₁ and M₂ of magnetized layers 110 and 130, respectively. Additional metal layers can be added to form electrodes 140 and 150 that improve conductivity and/or chemical resistance.

FIG. 2 illustrates a magnetic sensor 200 according to another embodiment of the present invention. Sensor 200 includes magnetized regions 210 and 230 that are on the same surface of a semiconductor layer 220. An insulating region 235 on the surface of semiconductor layer 220 separates magnetized region 210 from magnetized region 230. Accordingly, when a bias voltage V₀ having the polarity illustrated in FIG. 2 is applied between magnetized regions 210 and 230, magnetized region 210 injects spin-polarized electrons through semiconductor region 220 into magnetized region 230. A δ-doped layer 215 (and/or 225) and an optional transition layer 221 (and/or 223) are at the interface of magnetized layer 210 (and/or 230) with semiconductor layer 220 to improve the efficiency of spin polarization.

Magnetized regions 210 and 230, semiconductor layer 220 with transition layers 221 and 223, and δ-doped regions 215 and 225 of magnetic sensor 200 can be made of the same materials described above for magnetized layers 110 and 130, semiconductor layer 120 with transition layers 121 and 123, and δ-doped regions 115 and 125 of magnetic sensor 100. Magnetic sensor 200 of FIG. 2 differs from magnetic sensor 100 of FIG. 1 in that injected electrons in magnetic sensor 200 flow from magnetized region 210 down into semiconductor layer 220, laterally through semiconductor layer 220, and up into magnetized region 230. Accordingly, the distance traversed by electrons through semiconductor layer is at least equal to the width d of the insulating region 235 that separates magnetized regions 210 and 230. The average current path further predominantly depends on the width d of insulating region 235 and to a lesser extent on the widths d1 and d2 of magnetized regions 210 and 230, respectively. Generally, for spin ballistic transport, separation d should satisfy Equation (1).

Magnetic sensor 200 also differs from magnetic sensor 100 in the directions for magnetizations M₁ and M₂. In particular, magnetization M₁ is substantially perpendicular to the surface of magnetic sensor 200. To simplify creation of the desired magnetization M₁, magnetized region 210 can be made of a ferromagnetic material that is thin enough that the magnetization M₁ of magnetized region 210 has a tendency to align perpendicular to the surface, e.g., thickness t1 is preferably about 10 nm or thinner for a ferromagnetic material such as cobalt (Co). Magnetized region 230 has a thickness t2 that is greater than the thickness t1 of magnetized region 210 to simplify creation of magnetization M₂ in the plane of the surface of magnetized region 230.

Sensor 200 also includes an electrode 240 electrically connected to magnetized layer 210 and an electrode 250 electrically connected to magnetized layer 230. Electrodes 240 and 250 can be made of the same materials as electrodes 140 and 150 described above. FIG. 2 illustrates a configuration where electrode 240 is adjacent magnetized region 210 and electrode 250 is adjacent magnetized region 230. More generally, all or a portion of electrodes 240 and 250 can overlie the respective magnetized regions 210 and 230 and can contain an antiferromagnetic material to fix the magnetization directions as described above. Insulating layers 245 and 255 under respective electrodes 240 and 250 prevent shorting of the unmagnetized material to semiconductor layer 220 where electrodes 240 and 250 extend beyond underlying magnetized regions 210 and 230.

FIG. 3 illustrates a magnetic sensor 300 according to another embodiment of the invention. Sensor 300 includes a semiconductor layer 320 having a projection or mesa 322 with a width d that separates a magnetized region 310 from a magnetized region 330. Insulating dielectric layers 345 and 355 separate magnetized regions 310 and 330 from the underlying portions of semiconductor layer 320, and δ-doped semiconductor layers 315 and 325 and optional transition layers 321 and 323 are in or on sidewalls of mesa 322 and at the interfaces between semiconductor layer 320 and magnetized regions 310 and 330.

Magnetized regions 310 and 330, semiconductor layer 320 with transition layers 321 and 323, and δ-doped regions 315 and 325 of magnetic sensor 300 can be made of the same materials described above for magnetized layers 110 and 130, semiconductor layer 120 with transition layers 121 and 123, and δ-doped regions 115 and 125 of magnetic sensor 100. In magnetic sensor 300, magnetized regions 310 and 330 are separated by the width d of semiconductor mesa 322. Accordingly, the width d should satisfy Equation (1) to provide spin ballistic transport of electrons between magnetized regions 310 and 330.

Respective magnetizations M₁ and M₂ of magnetized regions 310 and 330 are parallel to the surface of magnetic sensor 300. As described further below, the orientation of magnetizations M₁ and M₂ permit magnetic sensor 300 to measure a magnetic field component H that is perpendicular to the surface of magnetic sensor 300.

An electrode 340 electrically connected to magnetized layer 310 and an electrode 350 electrically connected to magnetized layer 330 can be formed on and/or adjacent to magnetized regions 310 and 330. In sensor 300, the widths of magnetized regions 310 and 330 are not critical since the thicknesses and the length of magnetized regions 310 and 330 determine the size of the interfaces with semiconductor mesa 322.

In magnetic sensors 100, 200, and 300 of FIGS. 1, 2, and 3, the injection current of spin-polarized electrons from the first magnetized region 110, 210, or 310 through the semiconductor 120, 220, or 320 into the second magnetized region 130, 230, or 330 depends on orientation of magnetizations M₁ and M₂ and on how much the magnetic field H in the semiconductor 120, 220, or 320 rotates the spins of the injected electrons. A change in the magnetic field H generally changes the amount of rotation and therefore changes the current through the magnetic sensor.

The magnet-semiconductor (M-S) interfaces between the semiconductor and the first and second magnetized regions generally work as spin filters in magnetic sensor 100, 200, or 300. In particular, the conductivity G of the M-S-M heterostructure (e.g., through magnetized layer 110, semiconductor layer 120, and magnetized layer 130 in sensor 100) changes with the angle θ between the spin σ of electrons entering the second magnetized layer (e.g., layer 130) and the magnetization (e.g., magnetization M₂) of the second magnetized layer.

Equation (2) indicates the conductivity G of the magnetic sensors shown in FIGS. 1, 2, and 3. In Equation (2), G₀ has units of conductivity and is a geometry-dependent constant, in particular depending on the area of the magnet-semiconductor (M-S) interfaces. P₁ and P₂ in Equation (2) are the degrees of spin polarizations at the respective first and second M-S interfaces. For magnetic sensor 100 of FIG. 1, for example, P₁ and P₂ are degrees of spin polarization of injected electrons from magnetized layer 110 to semiconductor layer 120 and from magnetized layer 130 to semiconductor layer 120, respectively.

G=G₀(1+P₁P₂ cos θ) (2)

The current J in the heterostructure of magnetic sensor 100, 200, or 300 having the conductivity of Equation (2) is given in Equation (3), where V₀ is the voltage drop between the magnetized layers and θ is an angle between the spin σ of electrons incident on the second magnetized layer and the magnetization (e.g., M₂) of the second magnetized layer. If the magnetic field H in the semiconductor layer is zero, θ is equal an angle θ₀ of deviation from the perpendicularity between M₁ and M₂. When a component of the magnetic field H that is perpendicular to the spin σ is non-zero, the spin σ of the injected spin-polarized electrons precesses, and the angle θ is the sum of the deviation angle θ₀ and a precession angle θ_{H}. Thus, when magnetizations M₁ and M₂ are nearly perpendicular and the angle θ_{H} is small, the current J can be expressed as indicated in Equation (3).

J=V₀G=J₀(1+P₁P₂θ)=J₀[1+P₁P₂(θ₀+θ_{H})] (3)

The electron spin precession occurs with a frequency ω that is equal to γH where H is the magnetic field component normal to the spin σ and γ is the gyromagnetic ratio for electrons in the semiconductor. The gyromagnetic ratio γ is equal to γ₀ (m₀/m*) where γ₀ is 1.76×10⁷ Oe⁻¹s⁻¹ or 2.2×10⁵ m/sA, m₀ is the mass of a free electron, and m* is the effective mass of an electron in the semiconductor layer. Thus, the angular precession, i.e., the angle θ_{H} of the spin rotation, is about equal to γHτ_{d} and is less than or equal to the maximum angle θ_{Hmax} or γHτ_{S}, which would occur if the transit time τ_{d} were equal to the spin relaxation time τ_{S}. The spin-polarized current through the magnetic sensor has a component J_{S} that depends on the magnetic field H as indicated in Equation (4). When the magnetic field H changes with time, the signal component J_{S} has current gain K_{J} that is given in Equation (5).

J_{S}=J₀P₁P₂γHτ_{d}≦J₀P₁P₂γτ_{S}H (4)

K_{J}=dJ/dH=J₀P₁P₂γτ_{d}≦J₀P₁P₂γτ_{S} (5)

Theoretical calculations and experimental studies show that the longest values for spin-coherence time τ_{S} can be realized in negatively doped semiconductors (i.e., n-type semiconductors) and can reach about 1 ns in materials such as ZnSe and GaAs even at room temperature. Thus, if the product P₁P₂ is about 0.5 and the coherence time τ_{S} is about 10⁻⁹ seconds, the current gain K_{J} given by Equation (5) may be about 10⁻¹ J₀ Oe⁻¹ for m₀/m* about equal to 14 (e.g., in GaAs), i.e., K_{J} is greater than about 10⁻⁵ A/Oe for J₀=0.1 mA. Thus, for the perpendicular magnetic field component H about equal to 100 Oe, the current J_{S} as given in Equation (4) is larger than about 1 mA.

The current shot noise J_{N}, which is the current fluctuation reflecting the discrete character of electron charge, is equal to \sqrt{2qJΔf}=\sqrt{2qJ/τ_{S}}, where q represents the elementary charge and the frequency operation range Δf is τ_{S}⁻¹. For the example values given in the preceding paragraph, noise current J_{N} is less than 2 μA when J₀ is 0.1 mA, and the signal current J_{S} is greater than 1 mA, which is much more than the shot noise current J_{N}.

Magnetic sensors 100, 200, and 300 can be ultrafast. As noted above, the transit time τ_{d} is less than or equal to the spin-coherence time τ_{S} of the injected electrons. For a suitable n-doped semiconductor, the spin-coherence time τ_{S} can be less than or equal to about 1 ns. This means that the transit time τ_{d} is generally less than about 1 ns (e.g., τ_{d}<τ_{S}=1 ns). The effect of the magnetic field H on the spin injection and the spin precession can manifest as a change in the resistance or measurement signal in less than 1 ns. Changes in a magnetic field can thus cause more than a billion switching events per second when the magnetic sensor is used as a read head for magnetically stored data. Further, 1 ns is the maximum transit time τ_{d} at room temperature. More typically, the semiconductor layer can be made thinner than the maximum, so that the transit time τ_{d} can be about 0.1 to 0.01 ns or less, providing a faster device response.

Equation (4) indicates that the signal current J_{S} is proportional to a product of P₁ and P₂, i.e., to the degrees of spin polarizations at the first and second M-S interfaces of the heterostructure. Direct room-temperature spin injection from the conventional metal ferromagnets (FM) into semiconductors has been demonstrated but has a low efficiency (e.g., about 2%) at room temperature. The low spin injection efficiency makes operation of a very sensitive ultra fast magnetic sensor difficult at room temperature.

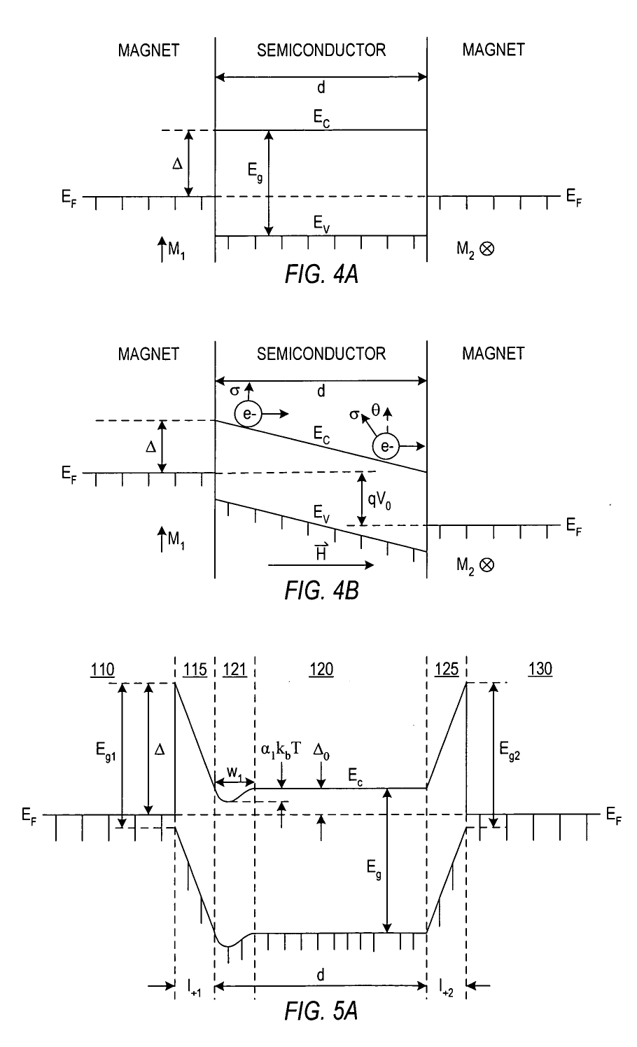

A principal difficulty of the spin injection from a ferromagnetic metal into a semiconductor is the high and wide potential (Schottky) barrier for electrons arising in the semiconductor near the metal-semiconductor interface. FIGS. 4A and 4B show energy band diagrams for a sensor having a magnet-semiconductor-magnet heterostructure similar to sensor 100, 200, or 300 but lacking δ-doped layers and transition layers. When the same voltage is applied to both magnetized regions (i.e., when the applied voltage V₀ is zero), the structure has electron energy bands as illustrated in 4A. In FIG. 4A, energy E_{C} is the bottom of the conduction band in the semiconductor layer and Δ is the band barrier height in the semiconductor layer.

Electrons in the ferromagnetic magnetized layers mostly fill the available electron states having energy below the Fermi energy E_{F} and must overcome the energy barrier of height Δ to enter the semiconductor layer. Numerous experiments indicate that the barrier height Δ is determined by the surface states forming at the semiconductor interface, and is approximately two-thirds of the band gap E_{g} in the semiconductor (i.e., Δ˜2/3E_{g}) independently of the type of ferromagnetic metal. Here band gap E_{g} is the band gap energy in the semiconductor layer, which is equal to the difference between the minimum energy E_{C} of the conduction band and the maximum energy E_{V} of the valence band (e.g., E_{g}≡E_{C}−E_{V}). For example, barrier height Δ is about 0.8 to 1.0 eV for gallium arsenide (GaAs) and about 0.6 to 0.8 eV for silicon (Si). In ordinary ferromagnet-semiconductor junctions as in FIG. 4A, the interface barrier makes the spin-polarized current from ferromagnets into semiconductors extremely small.

FIG. 4B shows the band structure of the same device as represented in FIG. 4A but with a non-zero applied bias voltage V₀. The bias voltage V₀ creates a relative difference qV₀ between energy levels of electrons in the two magnetized layers, but does not change the height Δ of the energy barrier for injecting electrons into the semiconductor material. The width of the barrier is also on the order of the thickness d of the semiconductor layer but depends on the magnitude of the applied voltage V₀ and the energy of the conduction electron.

To improve the spin injection efficiency, magnetic sensors 100, 200 and 300 of FIGS. 1, 2, and 3 have δ-doped layers, which are very thin and very heavily doped semiconductor, between the semiconductor and the magnetized regions. The magnetic sensors 100, 200, and 300 thus may be described as being M-n+-n-n+-M heterostructures.

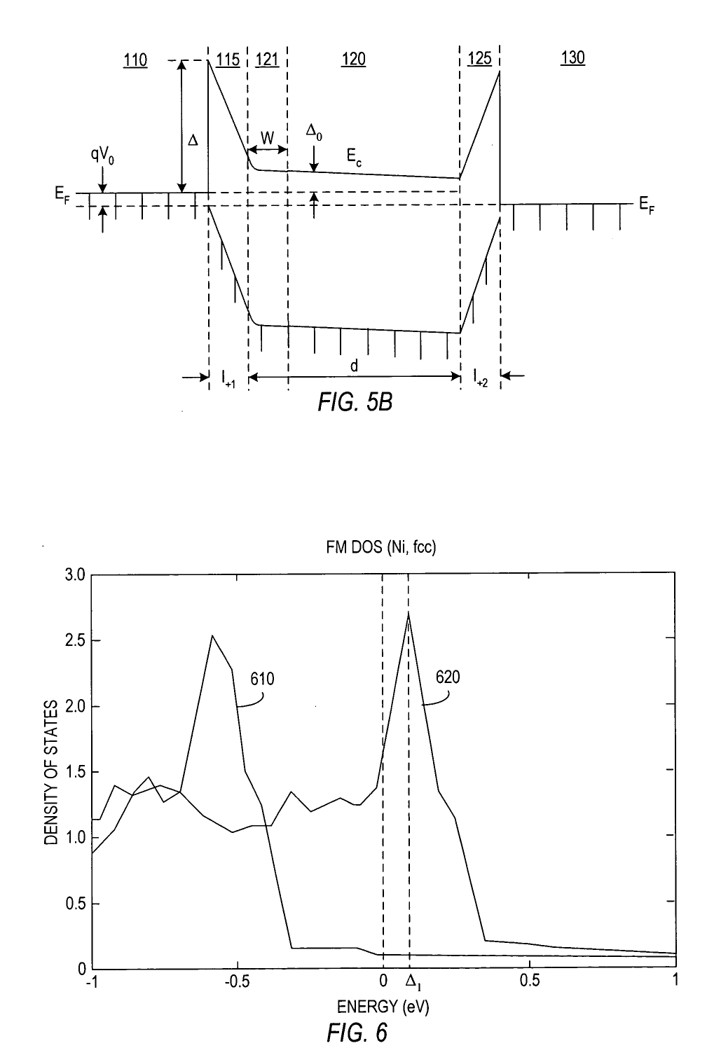

FIGS. 5A and 5B show the electron energy band structures of sensor 100 when the applied bias voltage V₀ is zero and non-zero, respectively. The electron energy band structure for sensors 200 and 300 will be substantially the same. As illustrated in FIG. 5A, δ-doped layers 115 and 125 greatly decrease the Schottky barrier width, which allows the spin-polarized electrons of energy greater than a barrier energy Δ₀ to easily tunnel through this very thin barrier 115 or 125 into semiconductor layer 120 where the potential barrier of height Δ₀ is present. Accordingly, if spin-polarized electrons have sufficient thermal energy to overcome the wide energy barrier Δ₀ of semiconductor layer 120, the spin-polarized electrons can overcome the energy barriers of height Δ by tunneling through the very thin δ-doped layers 115 and 125.

The δ-doped layers 115 and 125 are layers of a semiconductor material that is heavily doped with electron rich materials, and the respective donor concentrations N_{d1} and N_{d2} of δ-doped layers 115 and 125 are preferably much greater than the donor concentration N_{S} of the semiconductor layer 120 (i.e., N_{d1}, N_{d2}>>N_{S}). Examples of electron rich materials include P, As, and Sb for semiconductors such as Ge and Si. Materials like Ge, Se, Te, Si, Pb, and Sn are typically used to dope the semiconductor GaAs.

For efficient injection of spin-polarized current from magnetized layers 110 and 130 into semiconductor layer 120 at room temperature, δ-doped layers 115 and 125 should have respective donor concentrations N_{d1} and N_{d2} and respective thicknesses I₊₁ and I₊₂ that satisfy Equations (8) and (9). In Equations (8), ε₀ represents the permittivity of free space; ε represents the relative permittivity of semiconductor layer 120; Δ represents the height of the Schottky barrier (as measured from the Fermi level of the magnetized layers 110 and 130) at the boundaries between magnetized layer 110 and δ-doped layer 115 and between magnetized layer 130 and δ-doped layer 125; Δ₀ represents the height of the lower and wider potential barrier in semiconductor layer 120 (also as measured from Fermi level of magnetized layers 110 and 130); k_{B} is the Boltzmann's constant; T is temperature of the sensor; α₁ and α₂ are numerical factors between 1 and 4 and 0 and 4, respectively; q represents the elementary charge of an electron; and is the Planck's constant. For a GaAs δ-doped layer, m* is about 0.07 m₀ where m₀ is the mass of a free electron, and to is about 1 nm. Similarly, in a Si δ-doped layer, m* is about 0.2 m₀, and t₀ is about 0.5 mm.

$$\begin{matrix}{N}_{d1} {l}_{+ 1}^{2} \approx 2 \frac{{ϵ}_{0} ϵ ( Δ - {Δ}_{0} + {α}_{1} {k}_{B} T )}{{q}^{2}} , {N}_{d2} {l}_{+ 2}^{2} \approx 2 \frac{{ϵ}_{0} ϵ ( Δ - {Δ}_{0} + {α}_{2} {k}_{B} T )}{{q}^{2}} & ( 8 ) \\ {l}_{+ 1} \leq {t}_{0} = \sqrt{\frac{{ℏ}^{2}}{2 {m}^{*} ( Δ - {Δ}_{0} + {α}_{1} {k}_{B} T )}} , {l}_{+ 2} \leq {t}_{0} = \sqrt{\frac{{ℏ}^{2}}{2 {m}^{*} ( Δ - {Δ}_{0} + {α}_{2} {k}_{B} T )}} & ( 9 )\end{matrix}$$

Under the conditions of Equations (8) and (9), δ-doped layers 115 and 125 become “transparent” for tunneling electrons, and a suitable spin-polarized current occurs. In particular, electrons thermally excited to an energy greater than E_{F}+Δ₀ are emitted from magnetized layer 110 through δ-doped layer 115 into semiconductor layer 120 and then into magnetized layer 130 through the δ-doped layer 125.

The δ-doped layers 115 and 125 both have energy band gaps E_{gδ1} and E_{gδ1} that can be made less than the energy band gap E_{g} of semiconductor layer 120. This can be achieved by using a semiconductor material (e.g., GaAs) in the δ-doped layers 115 and 125 that differs from the semiconductor material (e.g., Ga₁₋ₓAlₓAs) used in the semiconductor layer 120. For example, δ-doped layers 115 and 125 can be GaAs, GeₓSi₁₋ₓ, InₓGa₁₋ₓAs, or Zn₁₋ₓCdₓSe when the semiconductor region is GaAs, Si, Ga₁₋ₓInₓAs, or ZnSe.

The terms α₁k_{B}T and/or α₂ k_{B}T in Equations (8) and (9) mark the presence of a shallow potential well with a depth about α₁k_{B}T and/or α₂ k_{B}T next to the first δ-doped layer and/or before the second δ-doped layer in the spatial profile of E_{C}(x). FIG. 5A illustrate an example where transition layer 121 is present creating the shallow potential well adjacent to δ-doped layer 115 when no bias voltage is applied. When a non-zero bias voltage is applied, biasing of the first junction up to the voltage V₁ of about α₁k_{B}T causes the shallow potential well to disappear as shown in FIG. 5B. As a result, the energy barrier Δ₀ of semiconductor layer 120 remains relatively flat, which improves the energy selectivity for conduction electrons. With proper selection of the energy barrier height Δ₀, this selectivity increases the efficiency of spin injection of the electrons from magnetized layer 110 into semiconductor layer 120. In particular, peculiarities of the density of states (“DOS”) in magnetic materials, such as ferromagnetic Ni, Co, and Fe can be matched with the barrier height in magnetic sensors 100, 200, and 300.

The DOS, which is commonly referred to as g(E)dE, indicates the number of electrons with energy between E and E+dE per unit volume. FIG. 6 illustrates separate plots 610 and 620 of the DOS respectively for spin-up and spin-down electrons in d angular momentum states in ferromagnetic Ni, when the magnetization is “down.” The densities of s and p angular momentum states are generally at least an order of magnitude smaller than the density of d angular momentum states in the energy range illustrated in FIG. 6. The energy origin chosen for FIG. 6 is the Fermi level E_{F}, i.e., E_{F}=0.

The d-state electrons are mainly responsible for the ferromagnetic properties of 3d-metals Fe, Co, Ni. The majority of the available d-electron states below the Fermi level correspond to spin up states, which gives ferromagnetic nickel (Ni) a magnetization directed down (with respect to a chosen spin quantization axis) since electrons are negatively charged. Plots 610 and 620 show a large difference in the density of states of minority and majority d-electrons at electron energies above the Fermi level (i.e., E>E_{F}). In particular, just above the Fermi level, the density of minority (spin down) d-electron states is much higher than the density of majority (spin up) d-electron states. The peak in the DOS of minority d-electron states is at an energy Δ₁, which for nickel (Ni) is at about 0.1 eV above the Fermi level EF. Similar peaks in the DOS at energies above the Fermi level exist in cobalt (Co) and iron (Fe). At this peak in the density of minority d electron states, the DOS for majority d electrons and the DOS of all s and p electrons are negligible when compared to the DOS of minority d electrons. Electrons that are injected from magnetized layer 110 into semiconductor layer 220 necessarily have energy above the Fermi level, and if the electrons injected from magnetized layer 110 have energy E about equal to Δ₁, the electrons would be almost 100% polarized (i.e., there will be mostly injected minority d electrons) due to the peculiarity of the DOS in ferromagnetic materials.

The materials of sensor 100, 200, or 300 are preferably selected so that the barrier energy Δ₀ is about equal to the energy Δ₁ corresponding to the peak density of minority d electrons. However, barrier energy Δ₀ can alternatively be in a range between 1 and 3 times (or more preferably between 1 and 1.5) times energy Δ₁. In this case, the degree of spin polarization P₁ of the injected electrons from magnetized layer 110 into semiconductor layer 120 is close to unity. The degree of spin polarization P₂ for injection from the second magnetized layer 130 into the semiconductor layer 120 similarly reflects the dominance of the density of states of the particular spin-direction at the energy of conduction electrons. Accordingly, the second δ-doped layer 125 should satisfy the same conditions as the first δ-doped layer 115. In particular, the condition of Equation (8) is preferably satisfied to the extent that a dispersion of barrier energy Δ₁ is equal to the width of the peak in DOS near Δ₁ shown in FIGS. 6A and 6B. Typically, this occurs if Equation (8) is accurate to within about 20%.

The δ-doped layers 115 and 125 are preferably doped as heavily as practicable and are as thin as practicable. In one embodiment, one or both of the first and second δ-doped layers 115 and 125 may be formed by heavily doping portions of semiconductor layer 120 with electron rich materials. Alternatively, one or both of the first and second δ-doped layers 115 and 125 may be formed by growing the n+-doped epitaxial layer on one or both sides of the n-doped semiconductor layer 120. Epitaxial growth of the first or second δ-doped layer 115 and 125 simplifies formation of a δ-doped layers having a narrower energy band gap than the energy band gap of the semiconductor layer 120, e.g., the band gaps E_{gδ1} and E_{gδ2} are less than the band gap E_{g} to reduce the energy barrier to electron injection. Additionally, electron affinities of the δ-doped layers 115 and 125 are preferably greater than an electron affinity of semiconductor layer 120 by a value close to Δ₁ so that the efficiency of spin polarization is high.

If one or both of the first and second Δ-doped layers are formed by epitaxial growth of a very thin heavily doped (i.e., n+ doped) and narrower energy band gap semiconductor layer, the parameters of the δ-doped layers 215 and 225, i.e., their respective donor concentrations N_{d1} and N_{d2} and their thicknesses 1₊₁ and 1₊₂ should satisfy the conditions of Equations (8) and (9) for efficient spin injection.

Examples of such heterostructures include M₁-GaAs—Ga₁₋ₓAlₓAs—GaAs-M₂ (i.e., n+-δ-doped layers are formed from GaAs and n-doped semiconductor layer is formed from Ga₁₋ₓAlₓAs), M₁-GeₓSi₁₋ₓ—Si—GeₓSi₁₋ₓ-M₂, and M₁-Zn₁₋ₓCdₓSe—ZnSe—Zn₁₋ₓCdₓSe-M₂, where quantities x and 1-x refer to the composition of the respective materials. Regarding the n+-δ-doped layers (e.g., GaAs, GeₓSi₁₋ₓ, and Zn₁₋ₓCdₓSe), their thickness 1₊₁ and 1₊₂ should be sufficiently thin such that the corresponding M-S interfaces become transparent for electron tunneling. The conditions of Equations (8) and (9) may be satisfied, for example, if the δ-doped layers 115 and 125 are such that the thickness 1₊₁ or 1₊₂ is less than or equal to about 2 nm and the donor concentration is greater than or equal to about 10²⁰ cm⁻³.

With references to FIGS. 5A and 5B, the operation of an embodiment of magnetic sensor 100 will be explained. (Sensors 200 and 300 operate in substantially the same manner as sensor 100.) First, at room temperature, bias voltage V₀ causes injection of spin-polarized electrons from magnetized layer 110 into semiconductor layer 120 through δ-doped layer 115. The δ-doped layer 115 and adjacent transition layer 121 can be optimized for efficient injection at room temperature as described above. The electrons that tunnel through the first δ-doped layer 115 meet another lower and wider potential barrier of height Δ₀ formed in semiconductor layer 120. It is preferred that the width d of the semiconductor layer 120 be wide enough to prevent tunneling electrons with energies below the barrier height Δ₀ from tunneling through the lower but wide barrier. Therefore only the electrons with energies above the barrier height due to thermo-emission will be able to overcome the barrier and traverse semiconductor layer 120. As noted above, the presence of graded doping or transition layers 121 and 123 in semiconductor layer 120 provides a flatter energy barrier for better selectivity of electrons passing through semiconductor layer 120. Thus, effective filtration of electrons by their energy and spin occurs.

The potential barrier Δ₀ in semiconductor layer 120 may be manipulated to a desired value Δ₁ by controlling the characteristics of layers 115, 121, 120, 123, and 125 in magnetic sensor 100, for example, by controlling the donor concentration N_{d1} and N_{d2} in the δ-doped layers 115 and 125 and the donor concentration N_{S} in the semiconductor layer 120. The height of the barrier may be substantially maintained if the donor concentration N_{S} and the width d of semiconductor layer 120 substantially satisfy the conditions of Equations (10) and (11). In Equations (10) and (11), quantities ε₀, ε, q, Δ₁, m*, and d are defined above. In Equation (11), a_{B} and E_{B} are the Bohr parameters and are respectively equal to 0.05 nm and 13.6 eV; m₀ is the mass of a free electron; T is the sensor temperature; and k_{B} is the Boltzmann constant. For example, the minimum thickness dₘᵢₙ is about 6 nm for GaAs and about 3 nm for Ge when Δ₁ and Δ₀ are about 0.1 eV and temperature T is 300° K. Under these circumstances, a semiconductor layer 120 having a thickness d greater than 10 nm and donor concentration N_{S} less than or equal to 10¹⁷ cm⁻³ should satisfy the conditions specified by Equations (10) and (11).

$$\begin{matrix}{N}_{s} \leq 2 \frac{{ϵ}_{0} {ϵΔ}_{1}}{{q}^{2} {d}^{2}} & ( 10 ) \\ d > {d}_{min} = {a}_{B} ( \frac{1}{{k}_{B} T} ) \sqrt{\frac{{m}_{0} {E}_{B} {Δ}_{1}}{{m}_{e}^{*}}} & ( 11 )\end{matrix}$$

The width d of semiconductor layer 120 according to Equations (1) and (11) should satisfy Equation (12). According to Equation (12), semiconductor layer 120 should be between about 10⁻⁶ cm and about 3×10⁻⁵ cm for typical parameters of Ge and GaAs.

$${d}_{min} = \frac{{a}_{B}}{{k}_{B} T} \sqrt{\frac{{m}_{0} {E}_{B} {Δ}_{1}}{{m}_{e}^{*}}} < d < {d}_{max} = \sqrt{{D}_{n} {τ}_{S}} \qquad ( 12 )$$

This is realized when the acceptor concentration, Nₐ₁ and Nₐ₂ in transition layers 121 and 123 and their thickness, w₁ and w₂, satisfy the conditions of Equations (13) and (14). In this case, the energy band diagram of the magnetic sensors shown in FIGS. 1, 2, and 3 has the form presented in FIGS. 5A and 5B.

$${N}_{a1} {w}_{1}^{2} \approx 2 \frac{{ϵ}_{0} ϵ ( {α}_{1} {k}_{B} T )}{{q}^{2}} , {N}_{α2} {w}_{2}^{2} \approx 2 \frac{{ϵ}_{0} ϵ ( {α}_{2} {k}_{B} T )}{{q}^{2}} \qquad ( 13 )$$

w₁≦l₊₁<<d, w₂<l₊₂<<d (14)

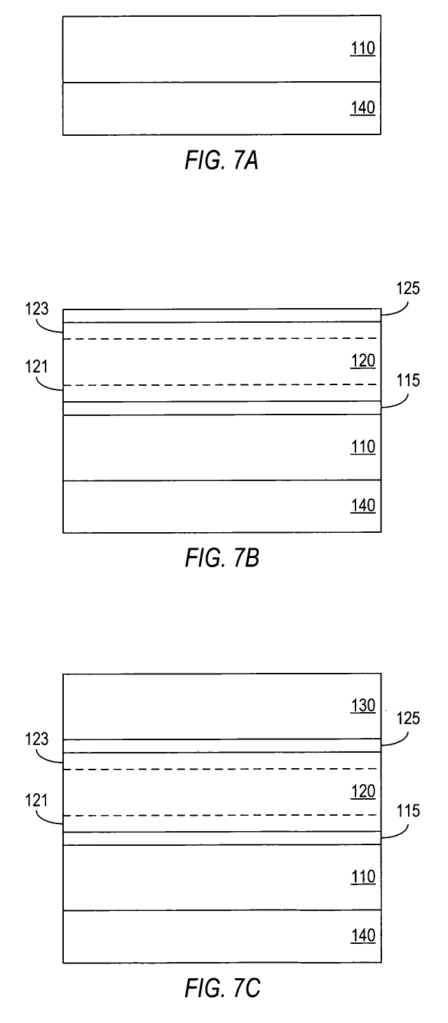

FIGS. 7A, 7B, and 7C illustrate an exemplary method of manufacturing the sensor 100 shown in FIG. 1. As shown in FIG. 7A, the process begins with substrate 140, which preferably contains a metal such as Ta, Cu, Ag, Au, and Pt. The thickness of substrate 140 is not critical, and an electrode (160 in FIG. 1) is optionally formed from highly conductive materials such as metals, doped silicon, and doped polysilicon on a bottom surface of substrate 140. Chemical mechanical polishing (CMP) or other planarization techniques can prepare the top surface of substrate 140.

Magnetized layer 110 is formed on the top surface of substrate 140. Magnetized layer 110 can include a ferromagnetic metal that is deposited, sputtered, or fired on substrate 140 in an applied magnetic field that sets magnetization M₁. An antiferromagnatic material could be used in underlying substrate 140 to help set magnetization M₁. A top surface of the resulting magnetized layer 110 can be planarized using CMP or other processes.

FIG. 7B shows the structure after formation of δ-doped layers 115 and 125 and semiconductor layer 120. In one formation process, a liquid epitaxial or molecular beam epitaxial growth forms δ-doped layer 115 of minimal practicable thickness (e.g., less than about 2 nm) and a high dopant concentration (e.g., greater than about 10²⁰ cm⁻³) on magnetic layer 110. The first δ-doped layer 115 may alternatively be deposited, sputtered, or fired onto magnetized layer 110. A liquid epitaxial or molecular beam epitaxial growth process, a deposition process, firing, or sputtering can then form semiconductor layer 120 on δ-doped layer 115. Transition layers 121 and 123 can be created by varying process parameters during the growth, deposition, or sputtering of semiconductor layer 120 or by implanting acceptors into semiconductor layer 120 after its formation. Liquid epitaxial or molecular beam epitaxial growth, a deposition process, sputtering, or firing onto semiconductor layer 120 can form a second δ-doped layer 125 that is substantially the same as δ-doped layer 115. Each of the δ-doped layers 115 and 125 and semiconductor layer 120 may be planarized after formation.

In an alternative process for forming the structure of FIG. 7B, semiconductor layer 120 is formed on the first magnetized layer 110, and δ-doped layers 115 and 125 are formed by heavily doping appropriate portions of semiconductor 120.

FIG. 7C shows the structure of FIG. 7B after addition of the second magnetized layer 130. Magnetized layer 130 may be formed by epitaxial growth, or may be deposited, sputtered, or fired onto δ-doped layer 225 while external magnetic field is applied to control the direction of magnetization M₂. As noted above, the magnetization M₂ of magnetized layer 130 should be substantially perpendicular to magnetization M₁ of magnetized layer 110 within an accuracy of about 30° and preferably within about 10°.

FIG. 1 shows the final structure of sensor 100 after the optional addition of electrodes 150 and 160. Electrodes 150 and 160 can be formed of a conductive material such as metal or a heavily doped semiconductor that sputtered, fired, or deposited on magnetized layers 110 and 130, respectively.

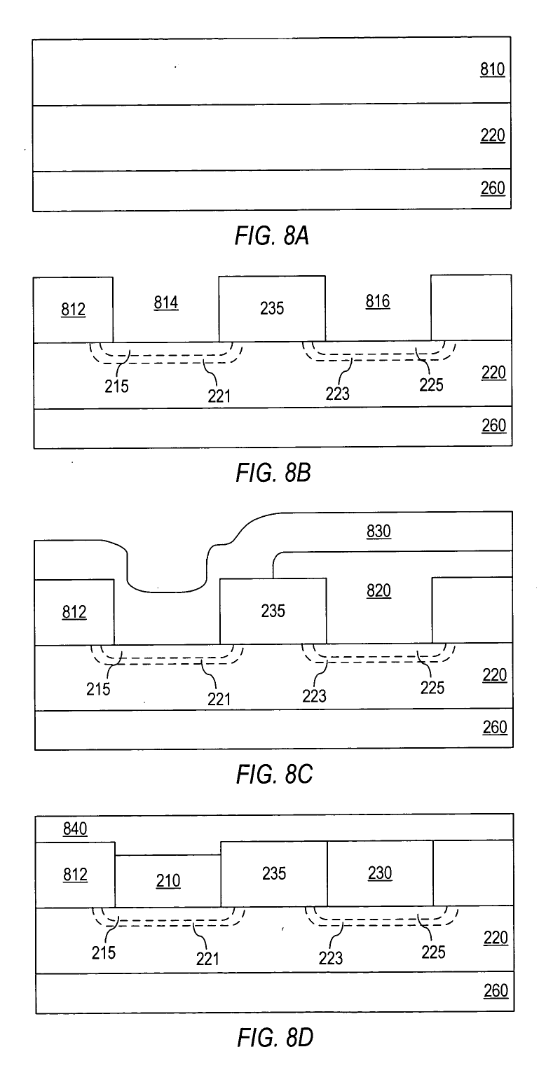

FIGS. 8A, 8B, 8C, and 8D illustrate a process for fabricating sensor 200 of FIG. 2. This process begins as illustrated in FIG. 8A with a substrate of a suitable material for growth or deposition of semiconductor layer 220. Semiconductor layer 220 is preferably made of a material such as negatively doped Si, GaAs, GaInAs, Ge, ZnSe, or ZnCdSe, which provides relatively long spin relaxation time τ_{S}. The thickness of semiconductor layer 220 is not critical since the spin injection current primarily flows laterally through semiconductor layer 220. An insulating layer 810 of oxide or other suitable material is formed on semiconductor layer 220 and patterned to create openings that will contain one or both magnetized regions 210 and 230. A precision process such as nano-imprint lithography can be used in patterning insulating layer 810. Nano-imprint lithography techniques suitable for such patterning are described, for example, in U.S. Pat. Nos. 6,432,740 and 6,579,742.

FIG. 8B shows a patterned insulating layer 812 containing openings 814 and 816. Semiconductor layer 220 is doped through openings 814 and 816 to respectively form transition layers 221 or/and 223, before formation of δ-doped layers 215 and/or 225. Ion implantation of acceptor ions and their diffusion at high temperature can be used to form transition layers 221 and 223. The δ-doped layers 215 and 225 can be formed by the ion implantation of donor ions and their thermo diffusion.

Magnetic regions 210 and 230 are formed in separate process steps to permit separate control of the directions of magnetizations M₁ and M₂. Either magnetized region 210 or 230 can be formed first. FIG. 8C illustrates the example of a process that forms magnetized region 210 first. In the illustrated process, a mask 820 of photoresist or another suitable material covers opening 816 during the formation of a thin magnetized layer 830. To make magnetization M₁ substantially perpendicular to the surface of the layer, magnetized material 830 is preferably a layer of ferromagnetic material such as cobalt having a thickness about equal to or less than 10 nm. Magnetic layer 830 and mask 820 are removed from above the surface of patterned insulating layer 812 using a process such as chemical polishing, and the remainder of mask 820 is removed from opening 816, leaving magnetized region 210 in opening 814. Magnetized region 230 can be formed using substantially the same process as used for formation of magnetized region 210 but with a different thickness to facilitate creating the desired magnetization M₂ in magnetic region 230.

An alternative process for forming magnetic regions 210 and 230 forms and patterns insulating layer 810 to include only one opening 814 for formation of the thinner magnetic region 210. The insulating layer 810 is then removed, and another patterned insulating layer (not illustrated) having an appropriate thickness and an opening 816 is used for formation of the thicker magnetic region 230.

After formation of magnetized regions 210 and 230 and removal of any masking material, an insulating layer 840 can be formed on the structure. Openings in insulating layer 840 can be formed where required for electrodes 240 and 250 to contact magnetic regions 210 and 220 as shown in FIG. 2.

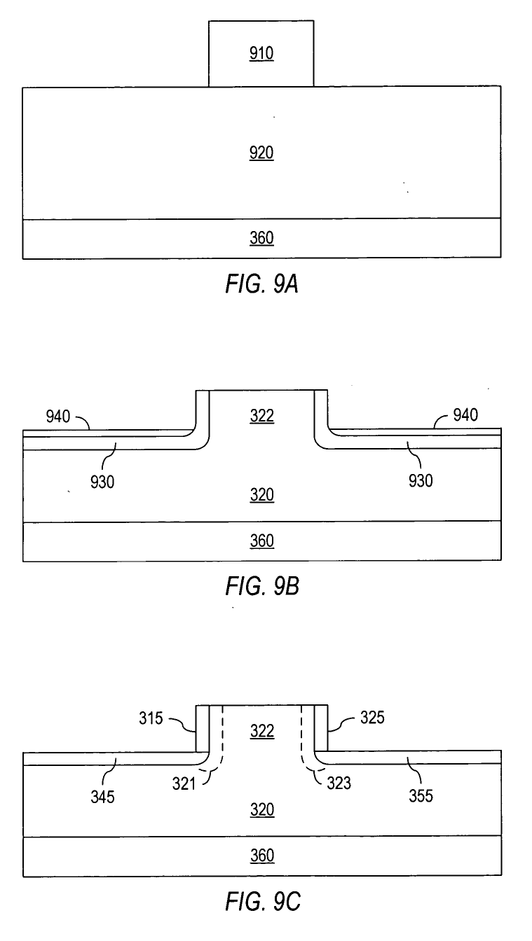

FIGS. 9A, 9B, and 9C illustrate a process for fabrication of sensor 300 of FIG. 3. As illustrated in FIG. 9A, the process begins with a substrate 360 on which a semiconductor layer 920 is grown or deposited. Semiconductor layer 920 can be of the same material as semiconductor layer 120 or 220 as described above. A mask 910 is formed on semiconductor layer 920 over the areas corresponding to mesa 322 of sensor 300. An etch process using mask 910 forms trenches in semiconductor layer 920 of a depth depending on the desired height of mesa 322, which may be between about 5 nm and about 30 nm high in an exemplary embodiment of the invention. The remaining mesa 322 between the trenches has a width d as described above.

An insulating layer 930 is formed in the trenches as shown in FIG. 9B. In an exemplary embodiment of the invention, insulating layer 930 is a thermal oxide of the material of semiconductor layer 320, but alternatively an insulating material can be deposited in the trenches to form insulating layer 930. A protective layer 940 of a material such as SiO₂ and Al₂O₃ can be coated on the bottom surface of insulating layer by a process such as directional sputtering that minimizes the material deposited on the sidewalls of mesa 322. Protective layer 940 allows etching to remove the portion of insulating layer 930 that is on the sidewalls of mesa 322, while preventing removal of the portions (i.e., insulating regions 345 and 355) of insulating layer 930 on the bottom surface of the trenches. A selective etching process can then remove protective layer 940 if desired.

Doping the portions of mesa 322 exposed by removal of the sidewall insulation forms transition layers 321 and 323 as illustrated in FIG. 9C. A deposition of a reactive metal on the sidewalls of mesa 322 can then be used to form δ-doped layers 315 and 325, after which any excess reactive metal can be removed from insulating regions 345 and 355. Following formation of δ-doped layers 315 and 325, magnetized regions 310 and 330 can be separately formed in the trenches to provide the desired magnetizations M₁ and M₂. Electrodes 340 and 350 are then formed adjacent to and/or on magnetized regions 310 and 330 as shown in FIG. 3

The above describes preferred embodiments of the invention along with some of its variations. The terms, descriptions, and figures used herein are set forth by way of illustration only and are not meant as limitations. Many variations are possible within the spirit and scope of the invention, which is intended to be defined by the following claims and their equivalents.

What is claimed is:

1. A magnetic sensor, comprising:
a first magnetized region;
a second magnetized region;
a semiconductor region in a path of a current between the first magnetized region and the second magnetized region, wherein the semiconductor region has a graded doping profile;
a first δ-doped layer between the first magnetized region and the semiconductor region; and
a second δ-doped layer between the second magnetized region and the semiconductor region.

2. The sensor of claim 1, wherein the graded doping profile of the semiconductor region includes a central region of a first dopant type and a first transition layer of a second dopant type adjacent to the first δ-doped layer.

3. The sensor of claim 2, wherein the first δ-doped layer and second δ-doped layer are of the first dopant type.

4. The sensor of claim 2, wherein the graded doping profile further includes a second transition layer of the second dopant type adjacent to the second δ-doped layer.

5. The sensor of claim 4, wherein the first dopant type is n-type, and the second dopant type is p-type.

6. The sensor of claim 2, wherein the first dopant type is n-type, and the second dopant type is p-type.

7. The sensor of claim 1, wherein the grade dopant profile of the semiconductor region comprises a transition layer adjacent to the first δ-doped layer, wherein the transition region has a band gap energy that is less than a band gap energy elsewhere in the semiconductor region.

8. The sensor of claim 1, wherein a height Δ₀ of a potential barrier between the semiconductor region and the first magnetized region about equal to an energy Δ₁ corresponding to a peak density of states for minority d-electron in the magnetized regions.

9. The sensor of claim 8, wherein the value of Δ₀ is preferably in the range Δ₁≦Δ₀≦3Δ₁.

10. The sensor of claim 1, wherein the first magnetized region has a first magnetization, and the second magnetized region has a second magnetization that is less than 30° from being perpendicular with the first magnetization.

11. The sensor of claim 1, wherein at least one of the first and second magnetized regions comprises at least one of Ni, Fe, Co, and alloys thereof.

12. The sensor of claim 1, wherein at least one of energy band gaps of the first and second δ-doped layers is narrower than an energy band gap of the semiconductor region.

13. The sensor of claim 1, wherein:
at least one of the first and second δ-doped layers comprises at least one of GaAs, GeₓSi₁₋ₓ, InₓGa₁₋ₓAs, and Zn₁₋ₓCdₓSe; and
the semiconductor region comprises at least one of GaAs, Si, Ga₁₋ₓInₓAs, and ZnSe.

14. The sensor of claim 1, wherein the semiconductor region comprises at least one of Si, GaAs, ZnTe, GaSb, GaP, Ge, InAs, CdSe, InP, InSb, CdTe, CdS, ZnS, ZnSe, AlP, AlAs, AlSb, and also alloys and combinations of these materials, including Ga₁₋ₓAlₓAs, Ga₁₋ₓInₓAs, Ga₁₋ₓInₓAs_{1-y}P_{y}, Zn₁₋ₓCd, and GeₓSi₁₋ₓ.

15. The sensor of claim 1, further comprising:
a first antiferromagnetic layer adjacent the first magnetized region; and
a second antiferromagnetic layer adjacent the second magnetized region.

16. The sensor of claim 15, wherein at least one of the first and second antiferromagnetic layers comprises at least one of FeMn, IrMn, NiO, MnPt, and α-Fe₂O₃.

17. A magnetic sensor comprising:
a substrate containing a semiconductor material;
a first magnetized region overlying a first area of a surface of the substrate, the first magnetized region forming a first interface with the semiconductor material; and
a second magnetized region overlying a second area of the surface of the substrate, the second magnetized region forming a second interface with the semiconductor material, wherein the first area and the second area are spaced laterally apart.

18. The sensor of claim 17, wherein the first interface is in the first area, and the second interface is in the second area.

19. The sensor of claim 18, further comprising an insulating region that is on the surface of the substrate and between the first magnetized region and the second magnetized region.

20. The sensor of claim 18, wherein the first magnetized region has a first magnetization that is substantially perpendicular to the surface of the substrate, and the second magnetized region has a second magnetization that is substantially parallel to the surface of the substrate.

21. The sensor of claim 17, wherein:
the substrate comprises a mesa containing the semiconductor material;
the first interface is at a first sidewall of the mesa; and
the second interface is at a second sidewall of the mesa.

22. The sensor of claim 21, wherein the first magnetized region has a first magnetization that is substantially parallel to the surface of the substrate, and the second magnetized region has a second magnetization that is substantially parallel to the surface of the substrate, and the first magnetization is substantially perpendicular to the second magnetization.

23. The sensor of claim 17, further comprising:
a first δ-doped layer in the first interface between the first magnetized region and the semiconductor material; and
a second δ-doped layer in second interface between the second magnetized region and the semiconductor material.

24. The sensor of claim 23, wherein the first and second δ-doped layers are n type, and the semiconductor material comprises a p-type layer at one of the first interface and the second interface.

25. The sensor of claim 23, further comprising a first transition layer between the first δ-doped layer and the semiconductor material.

26. The sensor of claim 25, wherein the first δ-doped layer is n-type and the first transition layer is p-type.

27. The sensor of claim 23, further comprising a second transition layer between the second δ-doped layer and the semiconductor material.

28. A method for forming a magnetic sensor, comprising:
forming a first magnetized region;
forming a second magnetized region;
forming a semiconductor region having a first interface with the first magnetized region and a second interface with the second magnetized region.
forming a first δ-doped layer at the first interface, between the first magnetized region and the semiconductor region; and
forming a first transition layer between the first δ-doped layer and the semiconductor region.

29. The method of claim 28, further comprising forming a second δ-doped layer at the second interface, between the second magnetized region and the semiconductor region.

30. The method of claim 29, further comprising forming a second transition layer between δ-doped layer and the semiconductor region.

31. The method of claim 28, wherein forming the first transition layer comprises doping a first portion of the semiconductor region at the first interface so that the first portion of the semiconductor region has a band gap energy that is less than a band gap energy elsewhere in the semiconductor region.

32. The method of claim 28, wherein the semiconductor region and the first δ-doped layer are n-type semiconductor, and the first transition layer is p-type semiconductor.

33. A method for forming a magnetic sensor, comprising:
forming a first magnetized region overlying a first area of a substrate including semiconductor, wherein the first magnetized region forms a first interface with the semiconductor material; and
forming a second magnetized region overlying a second area of the substrate, wherein the second magnetized region forms a second interface with the semiconductor material, the second area being laterally spaced from the first area.

34. The method of claim 33, wherein the first interface is in the first area of the substrate, and the second interface is in the second area of the substrate.

35. The method of claim 33, wherein the substrate comprises a mesa, the first interface is at a first sidewall of the mesa, and the second interface is at a second sidewall of the mesa.

36. The method of claim 33, further comprising:
forming a first δ-doped layer between the first magnetized region and the semiconductor material; and
forming a second δ-doped layer between the second magnetized region and the semiconductor material.

37. The method of claim 36, wherein forming the first δ-doped layer comprises doping a portion of the semiconductor material.

38. The method of claim 36, wherein the first and second δ-doped layers have n+ doping, and the semiconductor material comprises n-type material with p-type layers between the n-type material and the first and second δ-doped layers.

39. The method of claim 33 further comprising doping a first region of the semiconductor material at the first interface so that the first region has a band gap energy that is less than a band gap energy elsewhere in the semiconductor material.
